(19) United States
(12) Patent Application Publication
(10) Pub. No.: US 2014/0216806 A1
(43) Pub. Date: Aug. 7, 2014

(54) EMI GASKETS WITH PERFORATIONS

(71) Applicants: Michael Poulsen, House Springs, MO (US); Sri Talpallikar, Lincoln, NE (US)

(72) Inventors: Michael Poulsen, House Springs, MO (US); Sri Talpallikar, Lincoln, NE (US)

(73) Assignee: Laird Technologies, Inc, Earth City, MO (US)

(21) Appl. No.: 13/762,031

(22) Filed: Feb. 7, 2013

(51) Int. Cl. H05K 9/00

(52) U.S. Cl. CPC H05K 9/0081
USPC 174/351

(57) ABSTRACT

According to various aspects, exemplary embodiments are disclosed of EMI shields, such as EMI gaskets. In an exemplary embodiment, the gasket includes a body of indefinite length. The gasket also includes a base with a generally flat outer surface, an upright portion extending generally upwardly away from the base, and a tail portion extending laterally away from the base. The base and the upright portion may intersect the tail portion at a fold line. One or more perforations and/or a crease may be along the fold line.

### FIELD

The present disclosure generally relates to electromagnetic interference (EMI) gaskets.

### BACKGROUND

This section provides background information related to the present disclosure which is not necessarily prior art.

During normal operation, electronic equipment can generate undesirable electromagnetic energy that can interfere with the operation of proximately located electronic equipment due to electromagnetic interference (EMI) transmission by radiation and conduction. The electromagnetic energy can be of a wide range of wavelengths and frequencies. To reduce the problems associated with EMI, sources of undesirable electromagnetic energy may be shielded and electrically grounded. Shielding can be designed to prevent both ingress and egress of electromagnetic energy relative to a housing or other enclosure in which the electronic equipment is disposed. Since such enclosures often include gaps or seams between adjacent access panels and around doors and connectors, effective shielding can be difficult to attain because the gaps in the enclosure permit transference of EMI therethrough. Further, in the case of electrically conductive metal enclosures, these gaps can inhibit the beneficial Faraday Cage Effect by forming discontinuities in the conductivity of the enclosure which compromise the efficiency of the ground conduction path through the enclosure. Moreover, by presenting an electrical conductivity level at the gaps that is significantly different from that of the enclosure generally, the gaps can act as slot antennae, resulting in the enclosure itself becoming a secondary source of EMI.

EMI gaskets have been developed for use in gaps and around doors to provide a degree of EMI shielding while permitting operation of enclosure doors and access panels and fitting of connectors. To shield EMI effectively, the gasket should be capable of absorbing or reflecting EMI as well as establishing a continuous electrically conductive path across the gap in which the gasket is disposed. These gaskets can also be used for maintaining electrical continuity across a structure and for excluding from the interior of the device such contaminates as moisture and dust. Once installed, the gaskets essentially close or seal any interface gaps and establish a continuous electrically-conductive path thereacross by conforming under an applied pressure to irregularities between the surfaces. Accordingly, gaskets intended for EMI shielding applications are specified to be of a construction that not only provides electrical surface conductivity even while under compression, but which also has a resiliency allowing the gaskets to conform to the size of the gap.

As used herein, the term “EMI” should be considered to generally include and refer to EMI emissions and RFI emissions, and the term “electromagnetic” should be considered to generally include and refer to electromagnetic and radio frequency from external sources and internal sources. Accordingly, the term shielding (as used herein) generally includes and refers to EMI shielding and RFI shielding, for example, to prevent (or at least reduce) ingress and egress of EMI and RFI relative to a housing or other enclosure in which electronic equipment is disposed.

### SUMMARY

This section provides a general summary of the disclosure, and is not a comprehensive disclosure of its full scope or all of its features.

According to various aspects, exemplary embodiments are disclosed of EMI shields, such as EMI gaskets. In an exemplary embodiment, the gasket includes a body of indefinite length. The gasket also includes a base with a generally flat outer surface, an upright portion extending generally upwardly away from the base, and a tail portion extending laterally away from the base. The base and the upright portion may intersect the tail portion at a fold line. One or more perforations and/or a crease may be along the fold line.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A depicts a cross-sectional view of a conventional generally D-shaped fabric-over-foam (FOF) electromagnetic interference (EMI) gasket affixed to a first substrate;

FIG. 1B shows the conventional D-shaped FOF EMI gasket of FIG. 1A with the additional detail of the introduction of a second substrate;

FIG. 1C shows a problem in the art associated with the shear force of the introduction of the second substrate to the conventional D-shaped FOF EMI gasket as seen in FIG. 1B.

FIG. 2A depicts the application of a conventional generally P-shaped FOF EMI gasket to a first substrate.

FIG. 2B shows the conventional P-shaped FOF EMI gasket of FIG. 2A affixed to the first substrate with the additional detail of the introduction of a second substrate.

FIG. 2C shows the compression of the conventional P-shaped FOF EMI gasket after the introduction of the second substrate as seen in FIG. 2C.

FIG. 2D shows a problem in the art associated with the attachment of the conventional P-shaped FOF EMI gasket of FIG. 2A to a first substrate.

FIG. 3 is a perspective view illustrating an exemplary embodiment of a fabric-over-foam (FOF) gasket including examples of perforations thereon.

FIG. 4 is a top view of the FOF gasket of FIG. 3 showing various dimensional features of the gasket.

FIG. 5 is a perspective view of a segment of the gasket of FIG. 3 adhered to a section of substrate and also illustrating the alignment of the perforations relative to the edge of the substrate.

FIG. 6A is a cross-sectional view of an alternative exemplary embodiment of a gasket that includes a tail portion and a bell-shaped upright portion.

FIG. 6B is a cross-sectional view of another alternative exemplary embodiment of a gasket that includes a tail portion and a rectangular-shaped upright portion.

### DETAILED DESCRIPTION

Example embodiments will now be described more fully with reference to the accompanying drawings.

According to various aspects, exemplary embodiments are disclosed of EMI shields, such as EMI gaskets. The gasket includes a body of indefinite length. The gasket may include a portion (e.g., tail portion, etc.) foldable or bendable around or about the edge of a first substrate having first and second surfaces. The gasket also includes means for relieving residual stresses that may be caused by the bending or folding of the gasket portion about the edge of the substrate. As disclosed herein, the gasket may include a crease and/or one or more perforations along a bend or fold line of the gasket.

In an exemplary embodiment, a gasket includes a base, an upright portion extending generally upwardly away from the base, and a tail portion extending laterally away from the base. The body has a generally P-shaped profile or other profile collectively defined by the tail portion, the base, and the upright portion. One or more perforations (e.g., holes, openings, cutouts, slits, notches, etc.) may be at or adjacent to the intersection of the tail portion with the upright portion and base. For example, the base and the upright portion may intersect the tail portion at a fold line, and the one or more perforations may be at or along the fold line. The one or more perforations are configured to relieve residual stresses that may be caused by the bending or folding of the tail portion about an edge of the substrate, which thus reduces the chances of the gasket lifting off of or separating from the substrate after installation. Alternatively, the gasket may include additional or different means for relieving the stresses at the fold line or bend, such as a crease along the fold line or bend. The crease may be in addition to or an alternative to the one or more perforations.

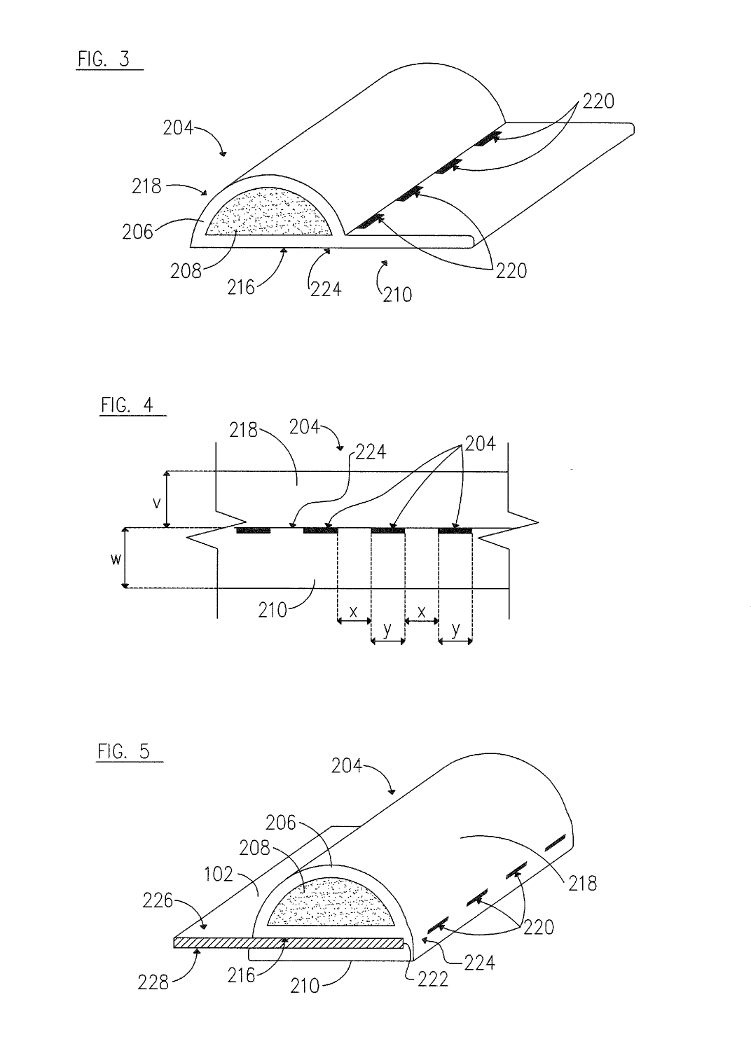

In some exemplary embodiments, the gasket includes a generally P-shaped profile (e.g., FIGS. 3 through 5, etc.). Alternative embodiments may include other suitable cross-sectional profiles, such as the profiles shown in FIG. 6A or FIG. 6B, etc. Some embodiments include the perforations being substantially identical (e.g., all being generally rectangular, equally sized and oriented, etc.) to each other and/or evenly spaced apart along the intersection between the upright portion and the tail portion.

In various exemplary embodiments, a gasket is provided that is deflectable into a collapsed orientation between first and second substrates. The gasket includes a body of indefinite length, a base (e.g., a generally flat leg or portion, etc.) having a generally flat outer surface, and an upright portion (e.g., generally vertical shape or member, etc.). The gasket further includes a tail portion that extends laterally away and generally parallel to the base in a free-standing state. Thus, the gasket may have a generally P-shaped profile (or other profile) collectively defined by the base, the tail, and the upright portion when the gasket is free-standing and uncompressed. One or more perforations (e.g., holes, openings, cutouts, slits, notches, etc.) may be adjacent, at, or about at the intersection or fold line of the upright portion and the tail portion. Alternative embodiments may have perforations at alternative or additional locations, and/or a crease along the fold line or intersection of the tail portion and the upright portion.

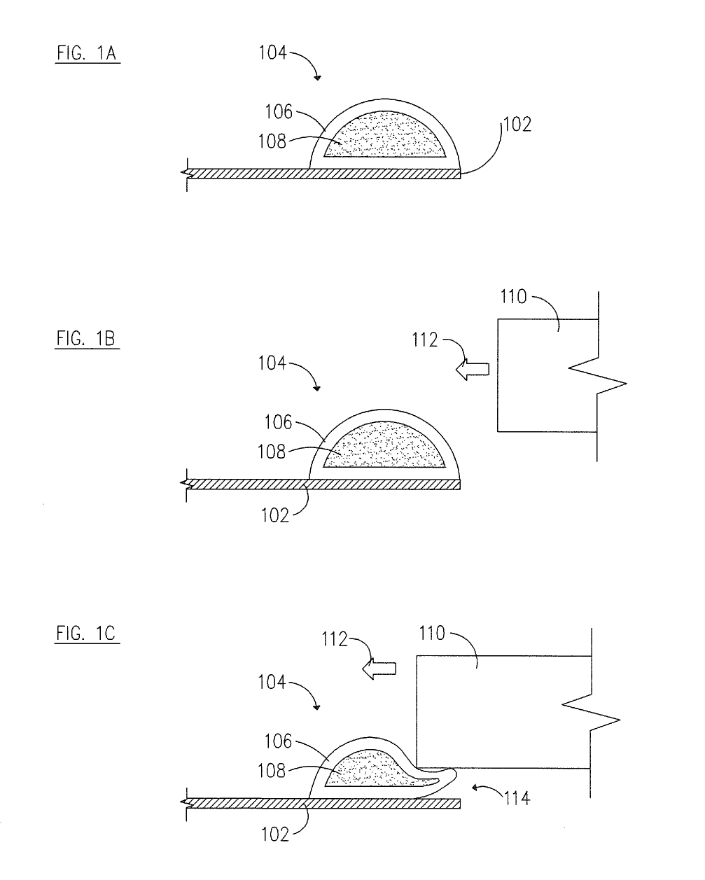

Turning to the Figures, FIGS. 1A-C and 2A-D depict prior art and are useful in explaining problems in the art that are addressed by a claimed EMI gasket. FIG. 1A shows a cross-sectional view of an essentially D-Shaped gasket 104 that has been adhered or affixed to a first substrate 102 at or near the edge of the substrate. This gasket 104 includes a foam core 108 wrapped by an outer fabric layer 106. In a particular application, the first substrate 102 may be a wall of a case or housing for electrical components such as a server rack, and the gasket 104 may be adhered to the inner cavity of the housing. In such an application, a second substrate 110 may be introduced to the gasket 104 in a direction indicated in FIG. 1B by the arrow 112, where the second substrate is a rail-mounted electrical component such as a server. In this application, the gasket 104 would serve as an EMI shield and seal between the two substrates 102, 110, which in this example are the server and the adjacent rack housing. But a problem in the art with such a D-Shaped gasket 104 is illustrated in FIG. 1C, where the shearing impact of the second substrate 110 may cause a portion of the gasket to separate from the first substrate 102, resulting in an undesirable breach 114 in the EMI shield's seal and potentially the partial destruction of a section of the gasket.

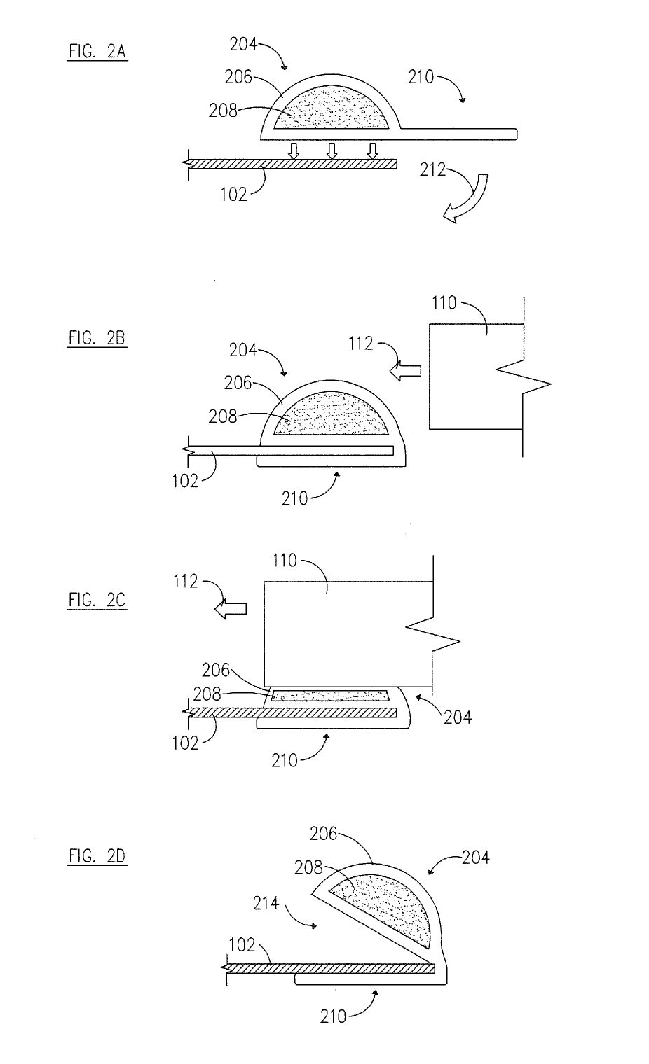

To address the shearing issue shown in FIG. 1C, P-Shaped gaskets 204 such as the one in FIG. 2A were developed. FIG. 2A shows a cross-sectional view of a P-Shaped gasket 204 that may be adhered or affixed to a first substrate 102. This gasket 204 also includes a foam core 208 wrapped by an outer fabric layer 206. But the gasket 204 additionally includes a tail of fabric 210 that extends away from the foam core 208. In applying this P-Shaped gasket 204 to a first substrate 102, the tail 210 is wrapped around the first substrate in a direction indicated by the arced arrow 212. Thus, when a second substrate 110 is applied via the arrow 112 in FIG. 2B, the tail section 210 prevents the shearing seen in FIG. 1C. The result is a properly-compressed and stationary gasket 204 as seen in FIG. 2C. But there is still a problem in the art with such a P-Shaped gasket 204 as can be seen in FIG. 2D where the foam core portion of the gasket has lifted off, separated, and detached from the substrate 102 at the point of bend in the tail portion, which is wrapped or bent around an edge of the substrate. This lifting off of the gasket from the substrate may be caused by residual stresses from the tail fabric bend and/or a hot melt adhesive if used to attach the fabric to the core.

FIG. 3 shows an exemplary embodiment of a claimed FOF EMI gasket 204 embodying one or more aspects of the present disclosure. This gasket 204 has a body of indefinite length. The gasket includes a foam core 208 surrounded by an outer fabric layer 206, where the outer fabric layer may be adhered to the foam core via hot melt adhesive or any other suitable adhesive known in the art. The gasket 204 also includes a base 216 having a generally flat outer surface. An upright portion 218 extends generally upwardly away from the base 216. A tail portion 210 extends laterally away and generally parallel to the base 216, such that the gasket 204 has a generally P-shaped profile collectively defined by the base 216, the tail portion 210, and the upright portion 218 when the gasket 204 is free-standing or uncompressed as shown in FIG. 3. The tail portion 210 may comprise two layers of the outer fabric layer adhered together via hot melt adhesive or any other suitable adhesive known in the art. Alternatively, other suitable shapes (e.g., rectangular, bell shaped, etc.) of the upright portion 218 may be used. Also, the tail portion 210 may comprise more or less than two layers of fabric and/or vary in length relative to that of the base 216.

As shown in FIG. 3, the gasket 204 includes perforations 220 along or adjacent to the fold line 224. The fold line 224 is defined as where the upright portion 218 and the base 216 meet or intersect the tail portion 210 throughout the length of the gasket 204. Thus, the fold line 224 may be referred to herein as the intersection of the tail portion 210 with the base 216 and upright portion 218. Alternative embodiments may have one or more perforations at other locations.

With continued reference to FIG. 3, the illustrated perforations 220 are generally rectangular in shape and are about equally sized. In addition, the perforations 220 are about evenly or equally spaced apart. In other embodiments, a gasket may include more or less perforations and/or in other configurations (e.g., different shapes. different sizes, at other locations, not equally spaced apart, etc.).

In this particular embodiment, the perforations 220 are formed such that they extend completely through the fold line 224 from one side to the other. Accordingly, the perforations 220 thus also extend completely through the gasket material(s) (e.g., fabric, etc.) located at or along the fold line 224 from one side to the other. By way of example, the perforations 220 may be formed by a rotary die cutter. Alternative processes may be used to form one or more perforations extending completely through or only partially through a gasket.

FIG. 4 is a top view of a section of gasket 204, which further illustrates the spacing of the perforations 220 along the fold line 224 between the upright portion 218 and the tail portion 210. Various ratios of the length of the base and upright portion, designated in FIG. 4 as v, to that of the tail portion, designated as w, may be used. Additionally, the spacing between the perforations, designated in FIG. 4 as x, as well as the length of the perforations themselves, designated as y, may additionally vary. Optimal or preferred values of x and y will be further discussed herein.

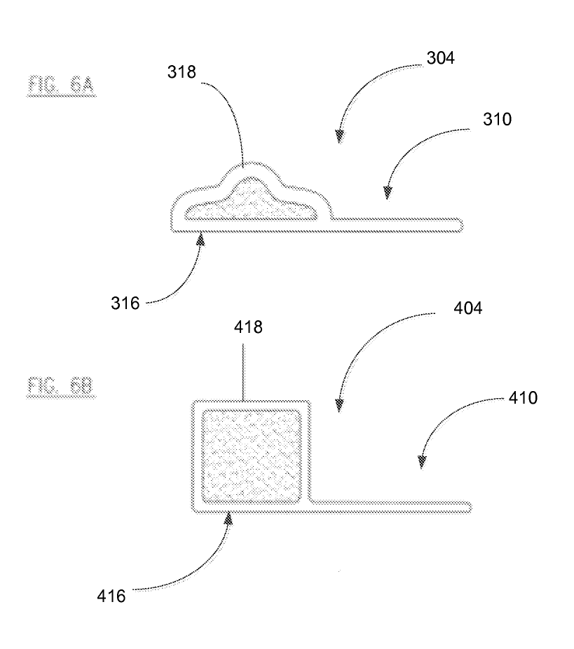

Depending on the particular end-use or application, the gasket's base 216 may be affixed or adhered (e.g., adhesively bonded using a pressure sensitive adhesive, etc.) to a first surface 226 of the first substrate 102. And, the tail portion 210 may be affixed or adhered to a second surface 228 of the first substrate as can be seen in FIG. 5 by bending the gasket 204 at the fold line 224 around the outer edge 222 of the first substrate. As shown in FIG. 5, the perforations 220 are aligned with the outer edge 222 of the first substrate 102 during installation of the gasket 204. To obtain all of the benefits of the perforations 220, the perforations 220 should be aligned with the outer edge 222 of the first substrate 102 during installation of the gasket 204 otherwise the benefits of the perforations will be mitigated or reduced. During use, the perforations 220 alleviate the force of the fabric layer as it tries to unfold from an installed position (as seen in FIG. 5) to an uninstalled, uncompressed position (as seen in FIG. 3), thereby preventing or inhibiting the failures in the art (as seen in FIG. 2D). The perforations 220 may be operable for relieving residual stresses at the bend, which thus reduces the chances of the gasket 204 lifting off or separating from the first substrate 102 after the gasket is applied to the first substrate.

Additionally, or alternatively, other exemplary embodiments may include different means for relieving the residual stresses at the bend than the perforations. For example, in another exemplary embodiment of a gasket, the means for relieving residual stresses at the bend comprises a crease along the fold line or bend, which crease may run the length of the gasket body. In this exemplary embodiment, heated rollers may be used to melt a hot melt adhesive on the fabric locally to help with the formation of the crease. In another exemplary embodiment of a gasket, the means for relieving residual stresses at the bend comprises the crease along the fold line and one or more perforations along the fold line.

The gasket 204 shown in FIGS. 3 through 5 may be compressed between a first substrate and a second substrate similar to the manner shown in FIGS. 2B and 2C. But the gasket 204 of FIG. 3 through 5 will not suffer from the failures of the gasket seen in FIG. 2D if optimal or preferred values and/or ratios of x and y are present, and the gasket is installed on the first substrate such that the perforations are aligned with the outer edge of the first substrate.

Referring to FIG. 4 and Table 1 below, a series of gaskets having dimensions of v=18 mm (millimeters), w=7 mm, and x=4 mm were tested for a tail portion bending force, where the value of y, defined as the length of the perforation, varied. Each gasket segment was 25 mm in length. The values in Table 1 are in kilogram force per inch width (kgf/inch width).

TABLE 1

| Sample No. | No Perforation | y = 4 mm | y = 6 mm | y = 8 mm |
|---|---|---|---|---|
| 1 | 0.131 | 0.071 | 0.046 | 0.040 |
| 2 | 0.150 | 0.113 | 0.058 | 0.040 |
| 3 | 0.151 | 0.103 | 0.061 | 0.033 |
| Average | 0.144 | 0.096 | 0.055 | 0.038 |

As can be seen in Table 1, the presence of perforations reduced the stresses on the gasket fabric that result from bending the gasket around the edge of the first substrate at the fold line. Additionally, the longer the perforations represented as higher values of y, the greater the reduction in the stress forces. The gaskets of Table 1 were additionally subjected to 24 hours of 70° Celsius heating in an oven. In each instance, the unperforated gaskets suffered the defect shown in FIG. 2D, where the upright portion separated from the first surface of the first substrate.

Table 2 below provides exemplary test results for additional gaskets having dimensions of v=18 mm, w=7 mm, and x=4 mm that were installed on the edge of a substrate as shown in FIG. 5. The value of y, defined as the length of the perforation, varied. The lengths of the gasket segments also varied in Table 2, as compared to those in Table 1, where the gasket segments were a consistent 25 mm in length. The gaskets of Table 2 were subjected to 24 hours of 70° Celsius heating in an oven to determine whether separation of the base of the gasket from the first surface of the substrate would occur.

TABLE 2

| Sample No. | Sample Length | No Perforation | y = 6 mm | y = 8 mm |
|---|---|---|---|---|
| 1 | 12.7 mm (0.5 in) | FAIL | FAIL | PASS |
| 2 | 12.7 mm (0.5 in) | FAIL | FAIL | PASS |
| 3 | 50.8 mm (2.0 in) | FAIL | FAIL | PASS |
| 4 | 50.8 mm (2.0 in) | FAIL | PASS | PASS |

As seen in Table 2, where a sample was marked FAIL, the defect seen in FIG. 2D was observed in that the gasket at least partially separated from the substrate. Conversely, a sample marked PASS maintained proper adhesion to the substrate. The samples of Table 2 were further subjected to 70° Celsius heating in an oven for an entire week, and the results in Table 2 remained consistent.

The test results shown in Tables 1 and 2 are provided only for purposes of illustration and not for purposes of limitation. Other exemplary embodiments of gaskets may be configured differently (e.g., sized differently, etc.) and/or produce different test results than that shown in Tables 1 and 2.

In an exemplary embodiment and with reference to FIG. 4, the ratio of x:y is 1:1, where y represents the length of the perforations 220 and x represents the length of the gap between the perforations along the fold line 224. In another exemplary embodiment, the ratio of x:y is 3:2. In yet another exemplary embodiment, the ratio of x:y is 2:1.

Though the scale of a claimed gasket need not be so limited by the following dimensions, in certain embodiments and applications the gasket may have values of v that range from about 3.3 mm to about 13.5 mm, and values of w that range from about 6.6 mm to about 10.0 mm. By way of further example, in certain embodiments and applications, the tail portion of the gasket may have a thickness that is less than about 2.8 mm, and the upright portion may have a height, perpendicular to the width v that ranges from about 2.5 mm to about 10.5 mm.

In some preferred embodiments, such as that seen in FIG. 3 through 5, the gasket 204 is a fabric-over-foam gasket with a resilient core member 208 (e.g., compressible foam, etc.) and an electrically-conductive outer fabric layer 206 coupled to the resilient core member 208. In one embodiment, the outer fabric layer 206 is a fabric material (e.g., nylon ripstop (NRS) fabric, etc.) coated with nickel/copper, the resilient foam core 208 comprises polyurethane foam, and a pressure sensitive adhesive is used to attach the fabric to the polyurethane foam core. In another embodiment, the core member 208 may be thermoplastic elastomer foam or a urethane foam. In an embodiment, the outer fabric layer 206 is a fabric material coated with tin/copper. Alternative embodiments may include other suitable materials for the core (e.g., resiliently compressible non-foam materials, other open-celled foam materials, etc.), the outer layer (e.g., nickel-plated polyester or taffeta fabric, nickel/copper plated knit mesh, etc.) and/or other bonding means for attaching the outer layer to the core.

The fabric layer 206 may be adhered to the core 208 with any suitable adhesive known in the art. In an embodiment, the adhesive may be an acrylic non-conductive pressure sensitive adhesive having a high peel strength and temperature resistance. In another embodiment, the adhesive may be an acrylic conductive pressure sensitive adhesive having an electrical conductivity. In another embodiment, the adhesive may be a solvent based polyester adhesive that is substantially halogen free and includes at least one halogen-free flame retardant.

As shown in FIGS. 3 and 4, the perforations 220 fully penetrate and pass completely through the fold line 224 (and through the gasket material at or along the fold line) between the upright portion 218 and the tail portion 210. The perforations 220 preferably allow the tail portion 210 to bend around the outer edge 222 of the first substrate 102 while helping the base 216 remain in substantial contact with the first surface 226, even in the absence of a second substrate 110.

The compression of the gasket 204 between the two substrates 102, 110 preferably helps the gasket establish electrical conductivity with the substrates sufficient for EMI shielding performance.

The gasket need not be limited to the P-Shaped gasket seen in FIG. 3 through 5. As can be seen in FIGS. 6A and 6B, non-limiting alternate embodiments of the shape of the gasket are embraced. For example, FIG. 6A shows a cross-sectional view of an alternative embodiment of a gasket 304. As shown in FIG. 6A, the gasket 304 includes a tail portion 310, a base 316, and a bell-shaped upright portion 318. The gasket 304 also includes one or more perforations along or adjacent to a fold line, which fold line is defined as where the upright portion 318 and base 316 meet or intersect the tail portion 310 throughout the length of the gasket. Such a bell shape shown in FIG. 6A may be more suitable for accepting a second substrate in certain circumstances than a P-shaped gasket.

FIG. 6B shows a cross-sectional view of an alternative embodiment of a gasket 404. As shown in FIG. 6B, the gasket 404 includes a tail portion 410, a base 416, and a rectangular-shaped upright portion 418. The gasket 404 also includes one or more perforations along or adjacent to a fold line, which fold line is defined as where the upright portion 418 and base 416 meet or intersect the tail portion 410 throughout the length of the gasket. Alternative embodiments may include an upright portion having a different shape (e.g., triangular, diamond shaped, circular, etc.) than the semi-circular shape shown in FIG. 3, bell shape shown in FIG. 6A, or rectangular shape shown in FIG. 6B.

In a particular embodiment, the gasket is an electromagnetic interference gasket having a body of indefinite length. The gasket includes a base, an upright portion extending away from the base, and a tail portion extending laterally away from the base. In this example, the upright portion comprises a foam core surrounded by an outer fabric layer adhered to the core. Also in this example, the base has a generally flat outer surface, and the tail portion includes two fabric layers adhered together. The base and the upright portion intersect with the tail portion at a fold line that runs the length of the gasket body. The gasket further includes one or more perforations along the fold line. The one or more perforations may be a series of perforations that run the length of the fold line. And, a gap may be between each pair of adjacent perforations, where the gaps are unperforated fabric layers that link the tail portion to the upright portion and the base.

An exemplary embodiment includes a fabric-over-foam electromagnetic interference gasket having a body of indefinite length. The gasket may include a base with a generally flat outer surface, an upright portion extending generally upwardly away from the base, and a tail portion. The tail portion is foldable or bendable around an edge of a first substrate having first and second surfaces. The body has a generally P-shaped profile or other profile collectively defined by the tail portion, the base, and the upright portion. One or more perforations may be at or adjacent to the intersection of the upright portion and the tail portion. The gasket may be compressed between the first surface of the first substrate and a surface of a second substrate into the collapsed orientation characterized in that the upright portion compresses generally between the substrates.

In further alternative embodiments, a gasket includes a body that is a generally hollow extrusion of elastomer material or other suitable material. The gasket may be formed by extruding an electrically-conductive elastomer material, such as silicone or fluorosilicone rubber rendered electrically-conductive by its loading with a silver-based filler and/or a nickel-based filler. The extruded gasket may include a base with a generally flat outer surface, an upright portion extending generally upwardly away from the base, and a tail portion. The tail portion may be foldable or bendable around an edge of a first substrate having first and second surfaces. The body may have a generally P-shaped profile or other profile collectively defined by the tail portion, the base, and the upright portion. One or more perforations may be provided or formed (e.g., cut into, etc.) at or adjacent the intersection of the tail portion with the upright portion and/or base. Other manufacturing processes besides extrusion can also be employed to make such a gasket, such as molding, die-cutting, etc.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally,” “about,” and “substantially,” may be used herein to mean within manufacturing tolerances. Or for example, the term “about” as used herein when modifying a quantity of an ingredient or reactant of the invention or employed refers to variation in the numerical quantity that can happen through typical measuring and handling procedures used, for example, when making concentrates or solutions in the real world through inadvertent error in these procedures; through differences in the manufacture, source, or purity of the ingredients employed to make the compositions or carry out the methods; and the like. The term “about” also encompasses amounts that differ due to different equilibrium conditions for a composition resulting from a particular initial mixture. Whether or not modified by the term “about,” the claims include equivalents to the quantities.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. An electromagnetic interference gasket comprising a body of indefinite length and including:
a base having a generally flat outer surface;
a tail portion extending laterally away from the base;
an upright portion extending away from the base, the upright portion and/or the base intersecting the tail portion at a fold line that runs the length of the gasket body; and
one or more perforations along the fold line.

2. The gasket of claim 1, wherein:
the one or more perforations comprise a series of perforations that run the length of the fold line;
the gasket further comprises a gap between each pair of adjacent perforations; and
the gaps comprise unperforated fabric layers that link the tail portion to the upright portion and the base.

3. The gasket of claim 2, wherein:
the perforations are substantially equal in length; and
the gaps between the perforations are substantially equal in length.

4. The gasket of claim 3, wherein:
the ratio of the length of the perforations to the length of the gaps between the perforations is 1:1; or
the ratio of the length of the perforations to the length of the gaps between the perforations is 3:2; or
the ratio of the length of the perforations to the length of the gaps between the perforations is 2:1.

5. The gasket of claim 2, wherein the one or more perforations are generally rectangular in shape.

6. The gasket of claim 1, wherein:
the body has a generally P-shaped profile collectively defined by the tail portion, the base, and the upright portion; or
the upright portion is bell shaped or rectangular.

7. The gasket of claim 1, wherein:
the tail portion is foldable around an edge of a substrate; and
the one or more perforations are configured to relieve residual stresses caused by folding of the tail portion about the edge of the substrate.

8. The gasket of claim 1, wherein the gasket is configured to be deflectable between a first substrate and a second substrate into a collapsed orientation characterized in that the upright portion compresses generally downwardly towards the base.

9. The gasket of claim 1, wherein the one or more perforations extend completely through the fold line.

10. The gasket of claim 1, wherein:
the tail portion comprises two fabric layers adhered together; and
the one or more perforations extend completely through the two fabric layers of the tail portion.

11. The gasket of claim 1, wherein:
the upright portion comprises a resilient core member that is surrounded by an outer electrically-conductive layer;
the outer electrically-conductive layer comprises fabric coated with one or more metals; and
the resilient core member comprises foam.

12. An electromagnetic interference gasket comprising a body of indefinite length and including:
a base having a generally flat outer surface;
a tail portion extending laterally away from the base;
an upright portion extending away from the base;
one or more perforations along an intersection of the tail portion with the base and/or the upright portion, wherein the one or more perforations comprise a series of perforations that run the length of intersection and completely penetrate through the gasket material along the intersection, the perforations being substantially equal in length and being generally rectangular in shape; and
wherein the gasket further comprising a gap between each pair of adjacent perforations, the gaps comprising unperforated fabric layers that link the tail portion to the upright portion and the base, the gaps between the perforations being substantially equal in length.

13. The gasket of claim 12, wherein:
the tail portion is foldable around an edge of a substrate; and
the one or more perforations are configured to relieve residual stresses caused by folding of the tail portion about the edge of the substrate.

14. The gasket of claim 12, wherein:
the ratio of the length of the perforations to the length of the gaps between the perforations is 1:1; or
the ratio of the length of the perforations to the length of the gaps between the perforations is 3:2; or
the ratio of the length of the perforations to the length of the gaps between the perforations is 2:1.

15. The gasket of claim 12, wherein the gasket is configured to be deflectable between a first substrate and a second substrate into a collapsed orientation characterized in that the upright portion compresses generally downwardly towards the base.

16. The gasket of claim 12, wherein:
the tail portion comprises two fabric layers adhered together; and
the one or more perforations extend completely through the two fabric layers of the tail portion.

17. The gasket of claim 12, wherein:
the upright portion comprises a resilient core member that is surrounded by an outer electrically-conductive layer;
the outer electrically-conductive layer comprises fabric coated with one or more metals; and
the resilient core member comprises foam.

18. The gasket of claim 1, wherein:
the body has a generally P-shaped profile collectively defined by the tail portion, the base, and the upright portion; or
the upright portion is bell shaped or rectangular.

19. An electromagnetic interference gasket comprising a body of indefinite length and including:
a base having a generally flat outer surface;
a tail portion extending laterally away from the base and foldable around an edge of a substrate;
an upright portion extending away from the base, the upright portion and/or the base intersecting the tail portion at a fold line that runs the length of the gasket body; and
means for relieving residual stresses caused by folding of the tail portion about the edge of the substrate.

20. The gasket of claim 19, wherein the means for relieving residual stresses comprises:
one or more perforations along the fold line; and/or
a crease along the fold line.
